(19) United States
(12) Patent Application Publication
(10) Pub. No.: US 2012/0068228 A1
(43) Pub. Date: Mar. 22, 2012

(54) HETEROJUNCTION BIOPLAR TRANSISTOR STRUCTURE WITH GaPSbAs BASE

(76) Inventors: Yu-Chung Chin, Taoyuan (TW); Tsung-Hsin Su, Taipei (TW)

(21) Appl. No.: 12/884,182

(22) Filed: Sep. 17, 2010

(51) Int. Cl. H01L 29/737

(52) U.S. Cl. 257/197; 257/E29.188

(57) ABSTRACT

A heterojunction bipolar transistor (HBT) structure with GaPSbAs base is disclosed. The HBT structure generally includes a substrate, a subcollector layer, a collector layer, a base layer, an emitter layer, an emitter cap layer, and a contact layer laminated from bottom to top sequentially, and optionally may further comprise a buffer layer between the substrate and the subcollector layer. The subcollector layer includes heavily-doped GaAs; the collector layer includes GaAs, InGaP, or AlGaAs; the base layer includes GaPAsSb compound; the emitter layer includes InGaP or AlGaAs; the emitter cap layer includes GaAs; the contact layer includes InGaAs; and the substrate includes semi-insulating GaAs. Since the base having GaPSbAs compound has lower band gap energy, the turn-on voltage of the transistors can be reduced. Furthermore, the GaPSbAs can form a type II band alignment with InGaP and AlGaAs emitters, the potential spike of the conduction band at the emitter-base interface is eliminated and thus further reduces the turn-on voltage of the transistors and reduces power consumption. As a result of the type II band alignment, the collector layer can be InGaP, or AlGaAs and other wide band gap materials, which increases the breakdown voltage and reduces the offset voltage and hence improves the power performance of the transistors.

### BACKGROUND OF THE INVENTION

1. Field of the Invention

The present invention relates to a heterojunction bipolar transistor (HBT) structure, and more particularly to a base layer with GaPSbAs.

2. The Prior Arts

Compared with the general Si-base field-effective transistor, the heterojunction bipolar transistor (HBT) manufactured by III-V elements having higher electron mobility has a lower distortion amplification characteristic for high frequency signal, such as L frequency band (1 to 2 GHz), C frequency band (4 to 8 GHz) or higher frequencies. Especially, it is suitable to apply in the electronic devices that require high linearity and low distortion, such as handset power amplifiers (PAs) in the wireless communication.

The heterojunction bipolar transistor mainly uses different materials for the emitter and the base, and generally, the bandgap energy of the emitter materials is higher than that of the base materials. Since the hole current from the base to the emitter is reduced by the valence band discontinuity (ΔEv) between the base and the emitter, the higher emitter injection efficiency and current gain can be obtained. The HBT turn-on voltage that plays an important role in device power consumption is dominated by the bandgap energy of the base material and by the conduction band discontinuity (ΔEc) of the base and emitter junction. Therefore, the lower base bandgap energy and ΔEc, the lower device power consumption and hence the longer battery life.

Nowadays, the semiconductor materials generally used for the emitter and the base are InGaP and GaAs, respectively, which has the advantage of high power, and high linearity.

However, the wide band gap energy (1.42 eV at room temperature) of the GaAs as a base material is a disadvantage in power consumption. In addition, the GaAs and wide bandgap materials such as InGaP and AlGaAs form a Type I band alignment, so that the wide bandgap material can not be used as a collector layer to increase the breakdown voltage because the collector current blocking effect occurs. Therefore, a heterojunction bipolar transistor which has a narrow bandgap energy of the base layer and a wide bandgap material as a collector layer without current blocking can solve the related problems.

### SUMMARY OF THE INVENTION

A primary objective of the present invention is to provide a structure of the heterojunction bipolar transistor with GaPSbAs base. The structure comprises a substrate, a subcollector layer, a collector layer, a base layer, an emitter layer and an emitter cap layer and a contact layer laminated from bottom to top sequentially, and further optionally comprises a buffer layer between the substrate and the subcollector layer, wherein the subcollector layer includes heavily-doped GaAs, the collector layer includes GaAs, and wide bandgap material, such as InGaP or AlGaAs, the base layer includes GaPSbAs compound, the emitter layer includes InGaP or AlGaAs, the emitter cap layer includes GaAs, AlGaAs and InGaP, the contact layer includes InGaAs, and the substrate includes semi-insulating GaAs. Since the GaPSbAs base can have lower band gap energy than that of GaAs, and lower electron affinity than those of the InGaP and AlGaAs, the turn-on voltage of the transistor can be reduced. In addition, since the wide band gap material can be used as the collector layer in the HBT, the breakdown voltage can be increased. Moreover, the collector layer and the emitter layer can be composed of InGaP or AlGaAs, which forms a double heterojunction bipolar transistor (DHBT), and thus the offset voltage of the DHBT is able to reduce.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is a scheme illustrating the heterojunction bipolar transistor structure with GaPSbAs base of the present invention.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

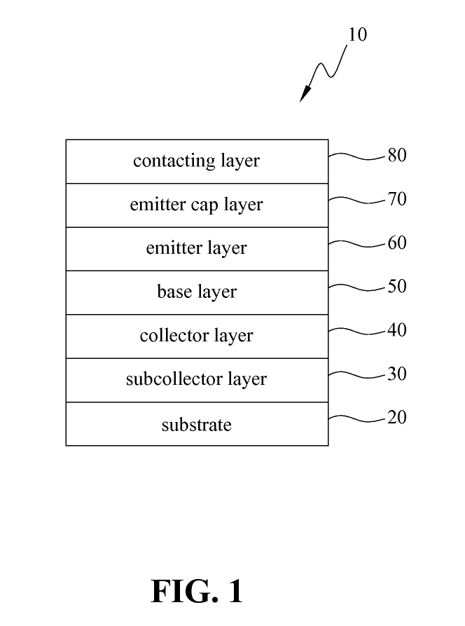

Referring to FIG. 1, the scheme illustrates the heterojunction bipolar transistor (HBT) structure with GaPSbAs base of the present invention. As shown in FIG. 1, the HBT structure 10 with GaPSbAs base comprises a subcollector layer 30, a collector layer 40, a base layer 50, an emitter layer 60, an emitter cap layer 70, and a contact layer 80 laminated from bottom to top sequentially on a substrate 20, wherein the substrate 20 includes semi-insulating (SI) GaAs, the subcollector layer 30 includes heavily-doped N type GaAs (N+ doped GaAs), the collector layer 40 includes one of the N type GaAs, N type InGaP, and N type AlGaAs or their combinations, the base layer 50 includes P type GaPSbAs compound (the chemical formula is GaPₓSb_{1-x-y}As_{y}, and 0<x≦1, 0≦y≦0.1), the emitter layer 60 includes one of N type GaAs, N type InGaP and N type AlGaAs, the emitter cap layer 70 includes one of the N type GaAs, N type InGaP, and N type AlGaAs or their combinations and the contact layer 80 includes N type InGaAs.

The characteristic of the present invention is that the base layer 50 composed of GaPₓAs_{y}Sb_{1-x-y} in the HBT structure of the present invention has lower band gap energy, the difference between the conduction band energy and the valence band energy, in comparison of the base layer composed of GaAs. Therefore, the turn-on voltage that the HBT structure requires can be reduced.

Another characteristic of the present invention is that the GaPₓAs_{y}Sb_{1-x-y} can be appropriately composed and compounded according to the HBT structure 10 of the present invention such that the base layer 50 and the material composing the collector layer 40, one of GaAs, InGaP, and AlGaAs or their combinations, can form the Type II band alignment, in the other words, the conduction band energy of the base layer 50 is higher than the conduction band energy of the GaAs, InGaP or AlGaAs, and the valence band energy of the base layer 50 is also higher than the valence band energy of the GaAs, InGaP or AlGaAs. Therefore, the collector layer 40 can be not only GaAs, but also the wide bandgap materials such as InGaP and AlGaAs without collector current blocking effect. Moreover, compared with the general GaAs collector layer with the same thickness and impurity concentration, the wide band-gap collector layer 40 of the present invention has higher breakdown voltage that is beneficial to high-voltage operation.

Another characteristic of the present invention is that the impurity concentration in the wide band-gap collector layer can be increased to improve the Kirk Effect, and hence improve the device ruggedness.

In addition, in comparison of the general GaAs collector layer with same breakdown voltage, the collector layer of the present invention can use wide bandgap material with thinner thickness to increase the cut-off frequency of the HBT. Another advantage is the thinner collector layer makes the whole collector layer become fully depleted, which results in the less changes of the base-collector junction capacitance with the bias voltages, and thus the linearity of the heterojunction bipolar transistor is further improved.

The heterojunction bipolar transistor structure with GaPSbAs base further optionally comprises a buffer layer (not shown) positioned between the substrate 20 and subcollector layer 30.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A heterojunction bipolar transistor structure with GaPSbAs base comprising:
a substrate;
a collector layer laminated on the substrate;
a base layer laminated on the collector layer, including P type GaPSbAs compound represented by chemical formula GaPₓSb_{1-x-y}As_{y}, and 0<x≦1, 0≦y≦0.1; and
an emitter layer laminated on the base layer.

2. The heterojunction bipolar transistor structure according to claim 1, further comprising a subcollector layer laminated between the substrate and the collector layer and including heavily-doped N type GaAs.

3. The heterojunction bipolar transistor structure according to claim 1, wherein the substrate includes semi-insulating GaAs.

4. The heterojunction bipolar transistor structure according to claim 1, wherein the collector layer includes one of the N type GaAs, N type InGaP, and N type AlGaAs or their combinations.

5. The heterojunction bipolar transistor structure according to claim 1, wherein the emitter layer includes one of the N type InGaP and N type AlGaAs.

6. The heterojunction bipolar transistor structure according to claim 2, further comprising a buffer layer laminated between the substrate and the subcollector layer.
